(19) United States
(12) Patent Application Publication
(10) Pub. No.: US 2009/0255723 A1
(43) Pub. Date: Oct. 15, 2009

(54) PRINTED CIRCUIT BOARD WITH GROUND GRID

(76) Inventor: Hui-Lung LAI, Sinshih Township (TW)

Correspondence Address: HDLS Patent & Trademark Services, P.O. BOX 220746, CHANTILLY, VA, 20153-0746, US

(21) Appl. No.: 12/103,191

(22) Filed: Apr. 15, 2008

(51) Int. Cl. H05K 1/00

(52) U.S. Cl. 174/266

(57) ABSTRACT

A printed circuit board with ground grid includes a first insulating plate, a plurality of first metal lines formed on the first insulating plate, a sub-circuit board above the plurality of first metal lines, a second insulating plate above the sub-circuit board, a plurality of second metal lines formed on the second insulating plate, and, a plurality of conductive components formed in and through the second insulating plate and the sub-circuit board to electrically connect the plurality of first metal lines and the plurality of second metal lines. As additional electronic elements and circuits can be located on the first insulating plate and/or on the second insulating plate without limitation, difficulties for printed circuit board layout can be dramatically reduced.

### BACKGROUND OF THE INVENTION

1. Field of the Invention

This invention generally relates to a printed circuit board, and in more particular, relates to a printed circuit board with ground grid.

2. Description of the Related Art

In conventional multi-layer printed circuit board, at least one copper plane is used as ground layer for electronic elements to provide electromagnetic shielding for the electronic elements located on the multi-layer printed circuit board to reduce electromagnetic interference from the outside of the electronic elements.

However, with the above structure, the electronic elements and their circuits can not be further installed on surfaces of the multi-layer printed circuit board which the ground layer is located on. Besides, while the ground layer is applied to a capacitance-sensing device such as a capacitive touch panel, the ground layer and other circuits are easy to form parasitic capacitor to effect original efficiency of the capacitance sensing device.

In the U.S. Pat. No. 7,207,104, a hybrid ground grid for printed circuit board is disclosed. In this patent, multilayer ground grids are formed by a plurality of hybrid ground lines separately located on both surfaces of an insulating plate. The hybrid ground lines on each surface of the insulating plate include groups of substantially parallel ground lines configured such that the groups of ground lines are positioned in transverse arrangement with other groups of ground lines formed on the same level. Such implementations have the ability to install electronic components and their circuits between any two ground lines on a surface of the insulating plate. As the ground lines interlaced areas on both surface of the insulating plate are reduced, the parasitic capacitor can be effectively decreased.

However, for the ground lines on either surface of the insulating plate, as the ground lines are straight lines and parallel to one another, the electronic component circuits can only extend along directions of the ground lines between any two ground lines. The electronic components are restricted on certain local area, and it is inconvenient for the circuit layout.

### SUMMARY OF THE INVENTION

Therefore, the main purpose of the present invention is to provide a printed circuit board with ground grid by interlacing and forming the first metal lines on the first insulating plate and the second metal lines on the second insulating plate. As additional electronic elements and circuits can be located on the first insulating plate and/or on the second insulating plate without limitation, difficulties for printed circuit board layout can be dramatically reduced.

In order to achieve the above said purpose, the present invention provides a printed circuit board with ground grid. The printed circuit board comprises a first insulating plate, a plurality of first metal lines interlaced and formed on the first insulating plate, a sub-circuit board above the plurality of first metal lines, a second insulating plate above the sub-circuit board, a plurality of second metal lines interlaced and formed on the second insulating plate, and, a plurality of conductive components formed in and through the second insulating plate and the sub-circuit board. Locations of the second metal lines and the first metal lines complementarily form a matrix, and the individual second metal lines has a plurality of overlapped parts overlapping the nearby individual first metal lines. The plurality of conductive components separately are formed in and through the plurality of overlapped parts of the second insulating plate and the sub-circuit board to connect the individual first metal lines and the corresponding individual second metal lines.

### BRIEF DESCRIPTION OF DRAWING

FIG. 1 illustrates a perspective view of a printed circuit board with ground grid in accordance with a first embodiment of the present invention;

FIG. 2 illustrates a top view of the printed circuit board in FIG. 1;

FIG. 3A illustrates a top view of the second metal lines of the printed circuit board in FIG. 1;

FIG. 3B illustrates a top view of the second metal lines of the printed circuit board in FIG. 1;

FIG. 4 illustrates a top view of a printed circuit board in accordance with a second embodiment of the present invention;

FIG. 5A illustrates a top view of the first metal lines of the printed circuit board in accordance with a third embodiment of the present invention;

FIG. 5B illustrates a top view of the second metal lines of the printed circuit board in accordance with a third embodiment of the present invention;

FIG. 6 illustrates a top view of a printed circuit board with ground grid in accordance with a third embodiment of the present invention;

FIG. 7 illustrates a top view of a printed circuit board with ground grid in accordance with a fourth embodiment of the present invention;

FIG. 8 illustrates a perspective view of a printed circuit board with ground grid in accordance with a fifth embodiment of the present invention;

FIG. 9 illustrates a perspective view of a printed circuit board with ground grid in accordance with a sixth embodiment of the present invention;

FIG. 10 illustrates another perspective view of a printed circuit board with ground grid in accordance with a sixth embodiment of the present invention;

FIG. 11 illustrates a perspective view of a capacitance-sensing device using the printed circuit board of the present invention; and

FIG. 12 illustrates another perspective view of a capacitance-sensing device using the printed circuit board of the present invention.

### DETAILED DESCRIPTION OF THE INVENTION

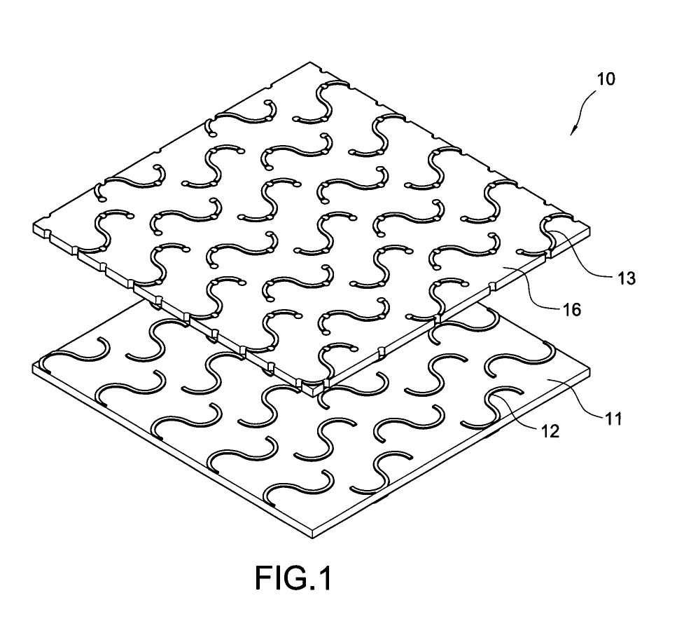

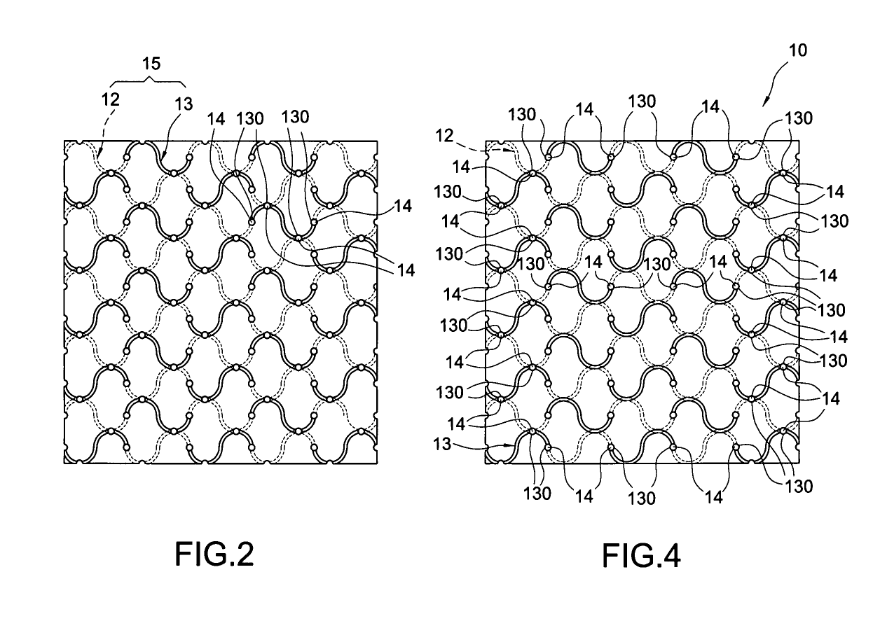

FIG. 1 and FIG. 2 illustrate a printed circuit board 10 with ground grid in accordance with a first embodiment of the present invention. As shown in FIG. 1 and FIG. 2, the printed circuit board 10 comprises a first insulating plate 11, a plurality of first metal lines 12 formed on one surface of the first insulating plate 11, a second insulating plate 16 correspondingly overlapping the first insulating plate 11, a plurality of second metal lines 13 formed on a surface of the second insulating plate 16, and a plurality of conductive components 14 formed in and through the second insulating plate 16, while the second insulating plate 16 correspondingly overlaps the first insulating plate 11.

After the second insulating plate 16 correspondingly overlaps the first insulating plate 11, the first metal lines 12 on the first insulating plate 11, and the second metal lines 13 on the second insulating plate 16 complementarily form a meshed matrix 15 as shown in a top view of the FIG. 2. Segments of the individual second metal lines 13 and nearby the first metal lines 12 form a plurality of overlapped portion 130, and the plurality of overlapped portion 130 appropriately overlap location of each conductive component 14 for connecting the first metal lines 12 and the second metal lines 12 to form a ground grid. In this embodiment, each conductive components 14 is a plated through hole formed by electroplating, however, and is not restricted by this.

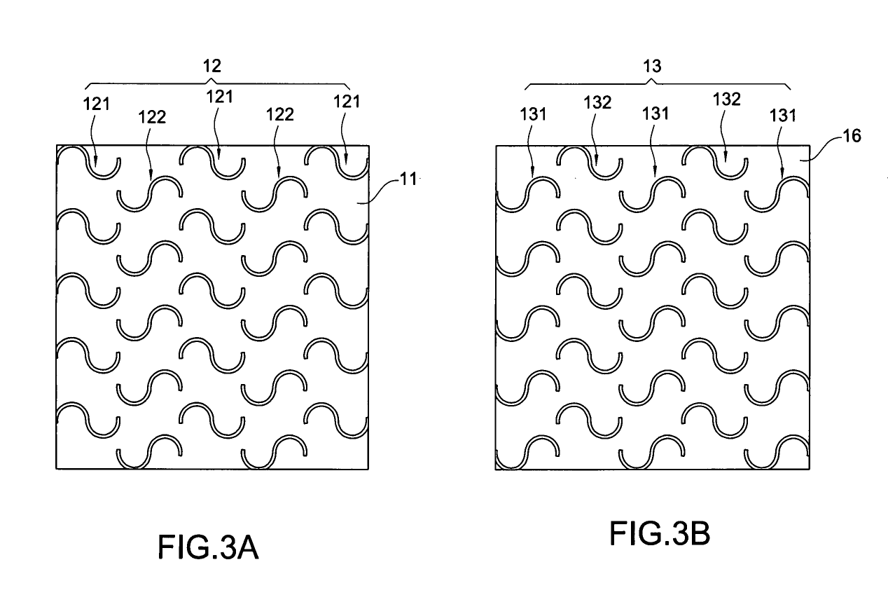

Referring to FIG. 3A, the first metal lines 12 includes curve line segments 121 and curve line segment 122. Shapes of curve line segments 121 of odd number columns are inverse to shapes of curve line segments 122 of even number columns of the first metal lines 12, and, vice versa, shapes of curve line segments 121 of odd number rows are inverse to shapes of curve line segments 122 of even number rows of the first metal lines 12. As shown in FIG. 3B, the second metal lines 13 includes curve line segments 131 and curve line segments 132. Shapes of curve line segments 131 of odd number columns are inverse to shapes of curve line segments 132 of even number columns of the second metal lines 13, and, vice versa, shapes of curve line segments 131 of odd number rows are inverse to shapes of curve line segments 132 of even number rows of the second metal lines 13. In this embodiment, the shape of the individual first metal lines 12 is substantially S-shaped or inverse S-shaped, and the shape of the individual second metal lines 13 is substantially S-shaped or inverse S-shaped.

In accordance with the ground grid of the present invention, each first metal trace 12 is not connected with nearby one another, and each second metal trace 13 is not connected with nearby one another. Therefore, circuit layouts of the electronic components and circuits located on the first insulating plate 11 and/or on the second insulating plate 16 are not restricted, and can be extended along and between the first metal lines 12 and the second metal lines 13 without being restricted inside certain local areas.

The method for manufacturing the printed circuit board 10 with ground grid in accordance with the above said present invention includes steps of individually processing two single-sided copper clad laminates with lithography process and etching process to obtain metal trace patterns shown in FIG. 3A and FIG. 3B, then, of putting bonded materials between the two copper clad laminates, and, finally, of pressurizing and heating the two copper clad laminates to obtain the printed circuit board 10.

FIG. 4 illustrates a printed circuit board with ground grid in accordance with a second embodiment of the present invention. In this second embodiment, the printed circuit board 10 is approximately the same as that of the first embodiment, and differences are that the conductive components 14 are not correspondingly formed in and through all the overlapped portions 130, and only are formed in and through a plurality of overlapped portions 130 of the second insulating plate 16. The plurality of overlapped portions 130 are overlapped portions of the individual second metal lines 13 and the first metal lines 12, are arranged in and along edges of the printed circuit board 10, and are along directions of rows of the matrix 15.

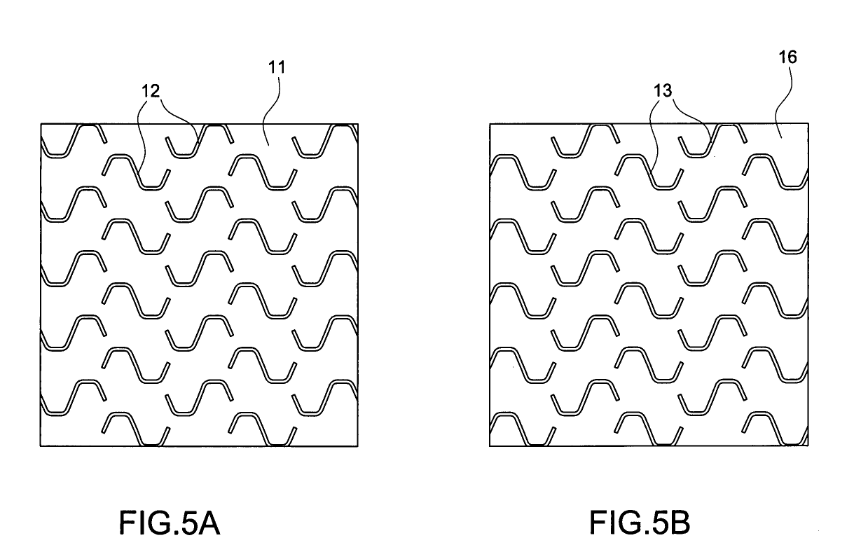

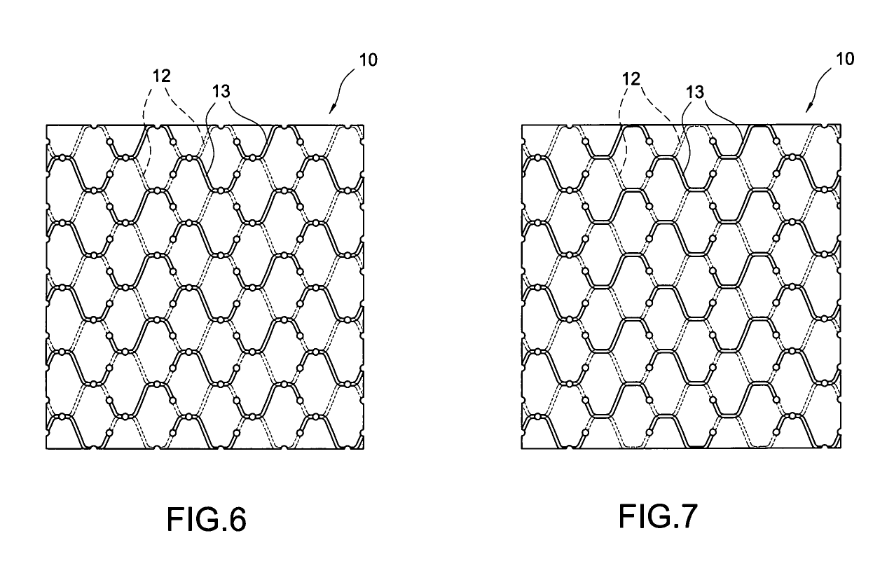

FIG. 5A, FIG. 5B, and FIG. 6 illustrate a printed circuit board with ground grid in accordance with third embodiment of the present invention. In this third embodiment, the printed circuit board 10 is approximately the same as that of the first embodiment, and differences are that shapes of the first metal lines 12 and of the second metal lines 13 are broken line-shaped, and, preferably, the broken portions are smooth.

FIG. 7 illustrates a printed circuit board with ground grid in accordance with a fourth embodiment of the present invention. In this fourth embodiment, the printed circuit board 10 is approximately the same as that of the second embodiment, and differences are that shapes of the first metal lines 12 and of the second metal lines 13 are broken line-shaped, and, preferably, the broken parts are smooth.

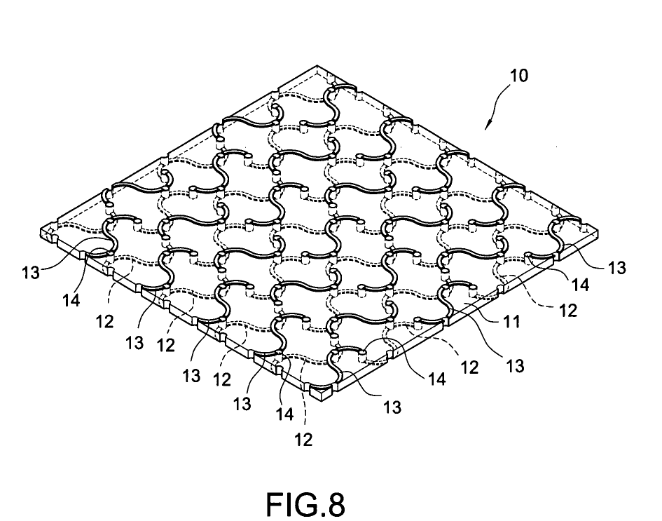

Besides, FIG. 8 illustrates a printed circuit board with ground grid in accordance with a fifth embodiment of the present invention. In this fifth embodiment, the printed circuit board 10 is approximately the same as that of the first embodiment, and differences are that the first metal lines 12 and the second metal lines 13 are separately and individually located on upper and lower surface of the insulating plate 11.

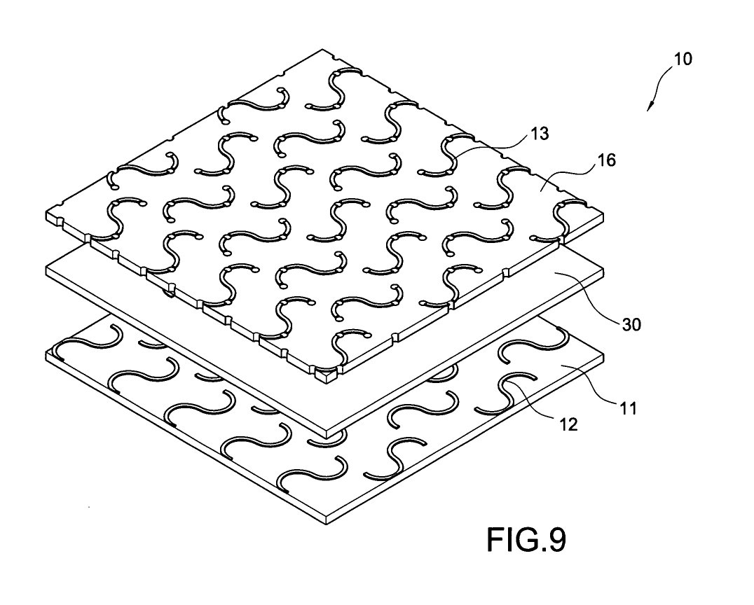

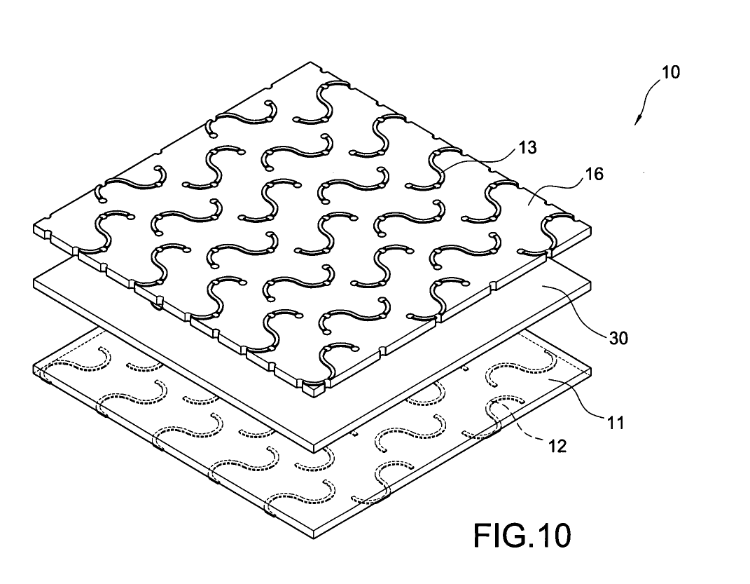

Furthermore, FIG. 9 illustrates a printed circuit board with ground grid in accordance with a sixth embodiment of the present invention. In this sixth embodiment, the printed circuit board 10 is approximately the same as that of the first embodiment, and differences are that the printed circuit board 10 further comprises a sub-circuit board 30 located between the first metal lines 12 and the second insulating plate 16 with electronic components and circuits (not shown) on its surface, and the conductive components 14 are formed in and through the second insulating plate 16 and the sub-circuit board 30 to connect the first metal lines 12 and the second metal lines 13. The first metal lines 12 and the second metal lines 13 located on different individual sides of the sub-circuit board 30 provide electromagnetic shielding for the electronic elements located on the sub-circuit board 30. As shown in FIG. 10, the first metal lines 12 are located on the lower surface of the first insulating plate 11.

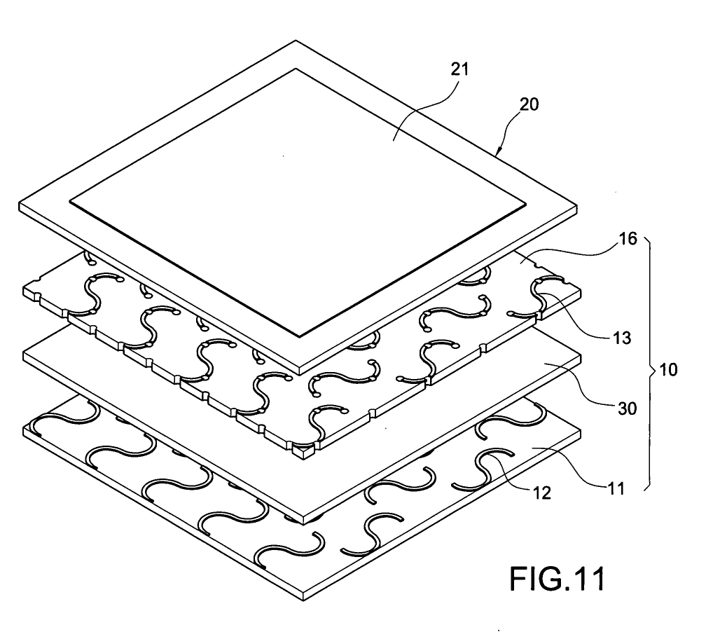

As shown in FIG. 11, a capacitance-sensing device uses the printed circuit board 10 in accordance with the present invention. Practically, for example, the capacitance-sensing device is a capacitive touch panel. The capacitance-sensing device comprises a printed circuit board 10 as shown in FIG. 9, and a touch panel 20 located above the printed circuit board 10.

The touch panel 20 includes a touch sensing part 21, and the touch sensing part 21 electrically connected to a correspondingly sensing circuit (not shown). The sensing circuit senses the electrical variation produced by the touch sensing part 21 due to finger touch, and determines the touched location of the touch sensing part 21.

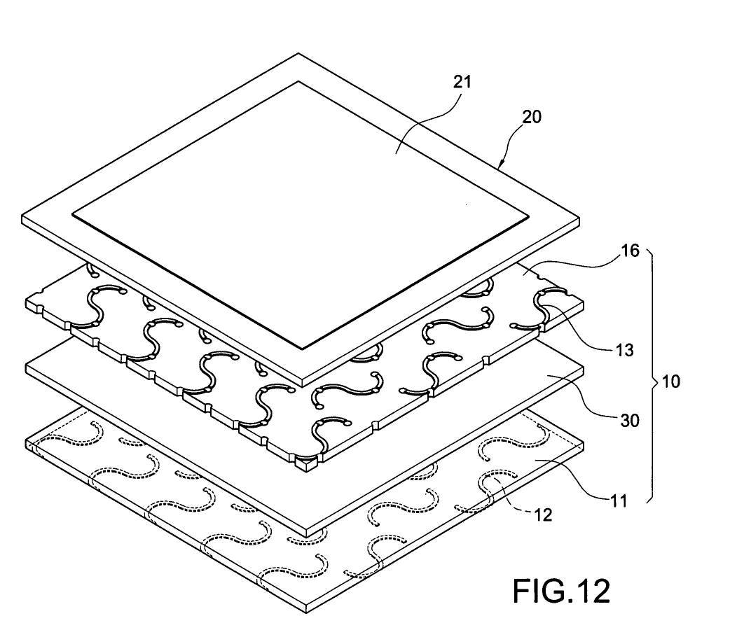

Besides, it is needed to explain that before the first metal lines 12 on the first insulating plate 11 contacts with the sub-circuit board 30, an insulating layer is located on an interface between the sub-circuit board 30 and the first metal lines 12 to prevent short circuit phenomenon. As shown in FIG. 12, the first metal lines 12 are located on the lower surface of the first insulating plate 11.

The printed circuit board 10 with ground grid of the present invention can really reduce the electrical influence to the touch sensing part 21.

As can be seen in the above description, the printed circuit board 10 of the present invention comprises the first metal lines 12, the second metal lines 13, and the conductive components 14. The printed circuit board 10 not only provides electromagnetic shielding for the electronic elements, but also makes the electronic element circuits layout more easier without limitations and reduces difficulties for printed circuit board layout to achieve effectiveness of the present invention.

If the invention has been described hereinafter with reference to specific embodiment, numerous variations and alternative configurations will be apparent to the man skilled in the art. Accordingly it will be apparent to the man skilled in the art that such variations and alternative configurations are also embraced by the present invention and the scope of the invention is restricted only in accordance with the accompanying claims and equivalents thereof.

What is claimed is:

1. A printed circuit board with ground grid, comprising:
a first insulating plate;
a plurality of first metal lines that are interlaced and formed on the first insulating plate;
a second insulating plate that correspondingly overlaps the first insulating plate;
a plurality of second metal lines that are interlaced and formed on the second insulating plate; and
a plurality of conductive components that are formed in and through a plurality of overlapped portions of the second insulating plate to connect the individual first metal lines and the second lines,
wherein the second metal lines and the first metal lines complementarily form a matrix, and the individual second metal lines has the plurality of overlapped portions overlapped with nearby the individual the first metal lines.

2. The printed circuit board as claimed in claim 1, wherein shapes of curve line segments of odd numbers columns of the first metal lines are inverse to shapes of curve line segments of even numbers columns of the first metal lines, and shapes of curve line segments of odd numbers columns of the second metal lines are inverse to shapes of curve line segments of even numbers columns of the second metal lines.

3. The printed circuit board as claimed in claim 2, wherein shapes of the first metal lines and shapes of the second metal lines are substantially S-shaped or inverse S-shaped.

4. The printed circuit board as claimed in claim 3, wherein shapes of the first metal lines and shapes of the second metal lines are curve line shaped.

5. The printed circuit board as claimed in claim 3, wherein shapes of the first metal lines and shapes of the second metal lines are broken line-shaped.

6. The printed circuit board as claimed in claim 5, wherein broken portions of the first metal lines and of the second metal lines are smooth.

7. The printed circuit board as claimed in claim 1, wherein the conductive components are plated through holes.

8. The printed circuit board as claimed in claim 1 further comprising a sub-circuit board that is between the first insulating plate and the second insulating plate, and correspondingly overlaps the first insulating plate and the second insulating plate.

9. A printed circuit board with ground grid, comprising:
a first insulating plate;
a plurality of first metal lines that are interlaced and formed on the first insulating plate;
a second insulating plate that correspondingly overlaps the first insulating plate;
a plurality of second metal lines that are interlaced and formed on the second insulating plate; and
a plurality of conductive components that are separately formed in and through individual overlapped portions of the second insulating plate to connect the corresponding individual first metal lines and the second metal lines,
wherein the second metal lines and the first metal lines complementarily form a matrix, the individual second metal lines has the plurality of overlapped portions overlapped with nearby the individual first metal lines, and the individual overlapped portions of the second insulating plate are arranged in edges of the matrix and are extended along directions of rows of the second metal lines.

10. The printed circuit board as claimed in claim 9, wherein shapes of curve line segments of odd numbers columns of the first metal lines are inverse to shapes of curve line segments of even numbers columns of the first metal lines, and shapes of curve line segments of odd numbers columns of the second metal lines are inverse to shapes of curve line segments of even numbers columns of the second metal lines.

11. The printed circuit board as claimed in claim 10, wherein shapes of the first metal lines and shapes of the second metal lines are substantially S-shaped or inverse S-shaped.

12. The printed circuit board as claimed in claim 11, wherein shapes of the first metal lines and shapes of the second metal lines are curve line shaped.

13. The printed circuit board as claimed in claim 11, wherein shapes of the first metal lines and shapes of the second metal lines are broken line-shaped.

14. The printed circuit board as claimed in claim 13, wherein broken portions of the first metal lines and of the second metal lines are smooth.

15. The printed circuit board as claimed in claim 9, wherein the conductive components are plated through holes.

16. The printed circuit board as claimed in claim 9 further comprising a sub-circuit board that is between the first insulating plate and the second insulating plate, and correspondingly overlaps the first insulating plate and the second insulating plate.

17. A printed circuit board with ground grid, comprising:
a insulating plate;
a plurality of first metal lines that are interlaced and formed on one side of the insulating plate;
a plurality of second metal lines that are interlaced and formed on the other side of the insulating plate; and
a plurality of conductive components that are formed in and through a plurality of overlapped portions of the insulating plate to connect the individual first metal lines and the second lines,
wherein the second metal lines and the first metal lines complementarily form a matrix, and the individual second metal lines has the plurality of overlapped portions overlapped with nearby the individual first metal lines.

18. The printed circuit board as claimed in claim 17, wherein shapes of curve line segments of odd numbers columns of the first metal lines are inverse to shapes of curve line segments of even numbers columns of the first metal lines, and shapes of curve line segments of odd numbers columns of the second metal lines are inverse to shapes of curve line segments of even numbers columns of the second metal lines.

19. The printed circuit board as claimed in claim 18, wherein shapes of the first metal lines and shapes of the second metal lines are substantially S-shaped or inverse S-shaped.

20. The printed circuit board as claimed in claim 19, wherein shapes of the first metal lines and shapes of the second metal lines are curve line shaped.

21. The printed circuit board as claimed in claim 19, wherein shapes of the first metal lines and shapes of the second metal lines are broken line-shaped.

22. The printed circuit board as claimed in claim 21, wherein broken portions of the first metal lines and of the second metal lines are smooth.

23. The printed circuit board as claimed in claim 17, wherein the conductive components are plated through holes.

24. A printed circuit board with ground grid, comprising:
a insulating plate;
a plurality of first metal lines that are interlaced and formed on one side of the insulating plate;
a plurality of second metal lines that are interlaced and formed on the other side of the insulating plate; and
a plurality of conductive components that are separately formed in and through individual overlapped portions to connect the corresponding individual first metal lines and the second metal lines,
wherein the second metal lines and the first metal lines complementaryly form a matrix, the individual second metal lines has the plurality of overlapped portions overlapped with nearby the individual first metal lines, and individual overlapped portions of the insulating plate are arranged in edges of the matrix and are extended along directions of the rows of the second metal lines.

25. The printed circuit board as claimed in claim 24, wherein shapes of curve line segments of odd numbers columns of the first metal lines are inverse to shapes of curve line segments of even numbers columns of the first metal lines, and shapes of curve line segments of odd numbers columns of the second metal lines are inverse to shapes of curve line segments of even numbers columns of the second metal lines.

26. The printed circuit board as claimed in claim 25, wherein shapes of the first metal lines and shapes of the second metal lines are substantially S-shaped or inverse S-shaped.

27. The printed circuit board as claimed in claim 26, wherein shapes of the first metal lines and shapes of the second metal lines are curve line shaped.

28. The printed circuit board as claimed in claim 26, wherein shapes of the first metal lines and shapes of the second metal lines are broken line-shaped.

29. The printed circuit board as claimed in claim 28, wherein broken portions of the first metal lines and of the second metal lines are smooth.

30. The printed circuit board as claimed in claim 24, wherein the conductive components are plated through holes.
